(19) United States
(12) Patent Application Publication
(10) Pub. No.: US 2022/0216048 A1
(43) Pub. Date: Jul. 7, 2022

(54) DOPED SILICON NITRIDE FOR 3D NAND

(71) Applicant: Applied Materials, Inc., Santa Clara, CA (US)

(72) Inventors: Tianyang Li, San Jose, CA (US); Deenesh Padhi, Sunnyvale, CA (US); Xinhai Han, Santa Clara, CA (US); Hang Yu, San Jose, CA (US); Chuan Ying Wang, Sunnyvale, CA (US)

(73) Assignee: Applied Materials, Inc., Santa Clara, CA (US)

(21) Appl. No.: 17/142,641

(22) Filed: Jan. 6, 2021

(51) Int. Cl. H01L 21/02

(52) U.S. Cl. CPC H01L 21/022; H01L 21/0214; H01L 21/02274; H01L 21/31116; H01L 21/02164; H01L 21/0228; H01L 21/02211; H01L 21/0217

(57) ABSTRACT

Exemplary methods of forming semiconductor structures may include forming a silicon oxide layer from a silicon-containing precursor and an oxygen-containing precursor. The methods may include forming a silicon nitride layer from a silicon-containing precursor, a nitrogen-containing precursor, and an oxygen-containing precursor. The silicon nitride layer may be characterized by an oxygen concentration greater than or about 5 at. %. The methods may also include repeating the forming a silicon oxide layer and the forming a silicon nitride layer to produce a stack of alternating layers of silicon oxide and silicon nitride.

### TECHNICAL FIELD

The present technology relates to semiconductor processes and materials. More specifically, the present technology relates to forming alternating layer film stacks.

### BACKGROUND

Integrated circuits are made possible by processes which produce intricately patterned material layers on substrate surfaces. Producing patterned material on a substrate requires controlled methods of formation and removal of exposed material. Stacked memory, such as vertical or 3D NAND, may include the formation of a series of alternating layers of dielectric materials through which a number of memory holes or apertures may be etched. Material properties of the layers of materials, as well as process conditions and materials for etching, may affect the uniformity of the formed structures. Material defects may lead to inconsistent patterning, which may further affect the uniformity of the formed structures.

Thus, there is a need for improved systems and methods that can be used to produce high quality devices and structures. These and other needs are addressed by the present technology.

### SUMMARY

Exemplary methods of forming semiconductor structures may include forming a silicon oxide layer from a silicon-containing precursor and an oxygen-containing precursor. The methods may include forming a silicon nitride layer from a silicon-containing precursor, a nitrogen-containing precursor, and an oxygen-containing precursor. The silicon nitride layer may be characterized by an oxygen concentration less than or about 30 at. %. The silicon nitride layer may be characterized by a density of less than or about 3.0 g/cm³. The methods may also include repeating the forming a silicon oxide layer and the forming a silicon nitride layer to produce a stack of alternating layers of silicon oxide and silicon nitride.

In some embodiments, the oxygen-containing precursor of the forming a silicon oxide layer and the oxygen-containing precursor of the forming a silicon nitride layer may be the same precursor. Forming the silicon nitride layer may include performing a plasma-enhanced deposition at a substrate temperature of greater than or about 500° C. Forming the silicon nitride layer may include performing a plasma-enhanced deposition at a plasma pulsing frequency of less than or about 10 kHz and a duty cycle of less than or about 50%. The oxygen concentration of the silicon nitride layer may be between about 10 at. % and about 30 at. %. A nitrogen atomic percent may be greater than or about 30 at. %. Forming the silicon nitride layer may include flowing the silicon-containing precursor and the nitrogen-containing precursor into a substrate processing region. The methods may include forming an amount of silicon nitride. The methods may include adding the oxygen-containing precursor while continuing to form silicon nitride. The oxygen-containing precursor may be flowed at a constant flow rate. The silicon nitride layer formed may include a bi-layer of silicon nitride substantially free of oxygen and silicon nitride characterized by an oxygen concentration greater than or about 5 at. %. The oxygen-containing precursor may be flowed at a varying flow rate. The silicon nitride layer formed may include a gradient of oxygen concentration through the silicon nitride layer. A flow rate of oxygen-containing precursor may be increased during the adding the oxygen-containing precursor. The methods may include forming one or more features through the stack of alternating layers of silicon oxide and silicon nitride. A lateral removal of the silicon nitride layer at an interface of the silicon nitride layer and an overlying silicon oxide layer may extend a distance less than or about 50% of a distance corresponding to a thickness of the silicon nitride layer.

Some embodiments of the present technology may encompass methods of forming a semiconductor structure. The methods may include forming a silicon oxide layer from a silicon-containing precursor and an oxygen-containing precursor. The methods may include forming a silicon nitride layer from a silicon-containing precursor, a nitrogen-containing precursor, and a phosphorus-containing precursor. The silicon nitride layer may be characterized by a phosphorus concentration less than or about 15 at. % and a density of less than or about 3.0 g/cm³. The methods may include repeating the forming a silicon oxide layer and the forming a silicon nitride layer to produce a stack of alternating layers of silicon oxide and silicon nitride.

In some embodiments, forming the silicon nitride layer may include performing a plasma-enhanced deposition at a substrate temperature of greater than or about 500° C. Forming the silicon nitride layer may include performing a plasma-enhanced deposition at a plasma pulsing frequency of less than or about 10 kHz and a duty cycle of less than or about 50%. The phosphorus concentration of the silicon nitride layer may be less than or about 10 at. %. A nitrogen atomic percent may be greater than or about 30 at. %. Forming the silicon nitride layer may include flowing the silicon-containing precursor and the nitrogen-containing precursor into a substrate processing region. The methods may include forming an amount of silicon nitride. The methods may include adding the phosphorus-containing precursor while continuing to form silicon nitride. The phosphorus-containing precursor may be flowed at a constant flow rate. The silicon nitride layer formed may include a bi-layer of silicon nitride substantially free of phosphorus and silicon nitride characterized by an phosphorus concentration greater than or about 1 at. %. Phosphorus may be incorporated in less than or about 30% of a thickness of the silicon nitride layer.

Some embodiments of the present technology may encompass methods of forming a semiconductor structure. The methods may include forming a silicon oxide layer from a silicon-containing precursor and an oxygen-containing precursor. The methods may include forming a silicon nitride layer from a silicon-containing precursor, a nitrogen-containing precursor, and a dopant precursor. The silicon nitride layer may be characterized by a dopant concentration less than or about 30 at. % and a density of less than or about 3.0 g/cm³. The methods may include repeating the forming a silicon oxide layer and the forming a silicon nitride layer to produce a stack of alternating layers of silicon oxide and silicon nitride. In some embodiments, forming the silicon nitride layer may include performing a plasma-enhanced deposition at a substrate temperature of greater than or about 500° C. Forming the silicon nitride layer may include performing the plasma-enhanced deposition at a plasma pulsing frequency of less than or about 10 kHz and a duty cycle of less than or about 50%.

Such technology may provide numerous benefits over conventional systems and techniques. For example, the processes and structures may protect against defect formation during etching operations. Additionally, the operations of embodiments of the present technology may improve memory hole formation through the stacks. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIGS. 2A-2C illustrate schematic cross-sectional views of substrate materials according to some embodiments of the present technology.

FIG. 3 shows selected operations in a formation method according to some embodiments of the present technology.

FIG. 4 illustrates a view of a notching of structures according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As 3D NAND structures grow in the number of cells being formed, the aspect ratios of memory holes and other structures increase, sometimes dramatically. During 3D NAND processing, stacks of placeholder layers and dielectric materials may form the inter-electrode dielectric or inter-poly dielectric (“IPD”) layers. These placeholder layers may have a variety of operations performed to place structures before fully removing the material and replacing it with metal. The IPD layers are often formed overlying a conductor layer, such as polysilicon, for example. When the memory holes are formed, apertures may extend through all of the alternating layers of material before accessing the polysilicon or other material substrate. Subsequent processing may form a staircase structure for contacts, and may also exhume the placeholder materials laterally.

A reactive-ion etching (“ME”) operation may be performed to produce the high aspect ratio memory holes. The ME process often involves a combination chemical and physical removal of the alternating layers, which may form a carbon polymer layer over sidewalls during etching, and which may protect layers from further etching. As one non-limiting example, where the alternating layers may include silicon oxide and silicon nitride, the silicon oxide may be removed to a greater degree by physical bombardment of the layer during the RIE, and the silicon nitride may be removed to a greater degree by chemical reaction of the RIE precursors with the nitride materials.

Conventional technologies may struggle with uniformity and control during the memory hole formation due to material differences between the two layer types, as well as the ME process and materials. The present technology overcomes these issues by adjusting material properties prior to the ME process, which may accommodate or limit one or more challenges that may otherwise occur. Although the remaining disclosure will routinely identify specific materials and semiconductor structures utilizing the disclosed technology, it will be readily understood that the systems, methods, and materials are equally applicable to a number of other structures that may benefit from aspects of the present technology. Accordingly, the technology should not be considered to be so limited as for use with 3D NAND processes or materials alone. Moreover, although an exemplary chamber is described to provide foundation for the present technology, it is to be understood that the present technology can be applied to virtually any semiconductor processing chamber that may allow the operations described.

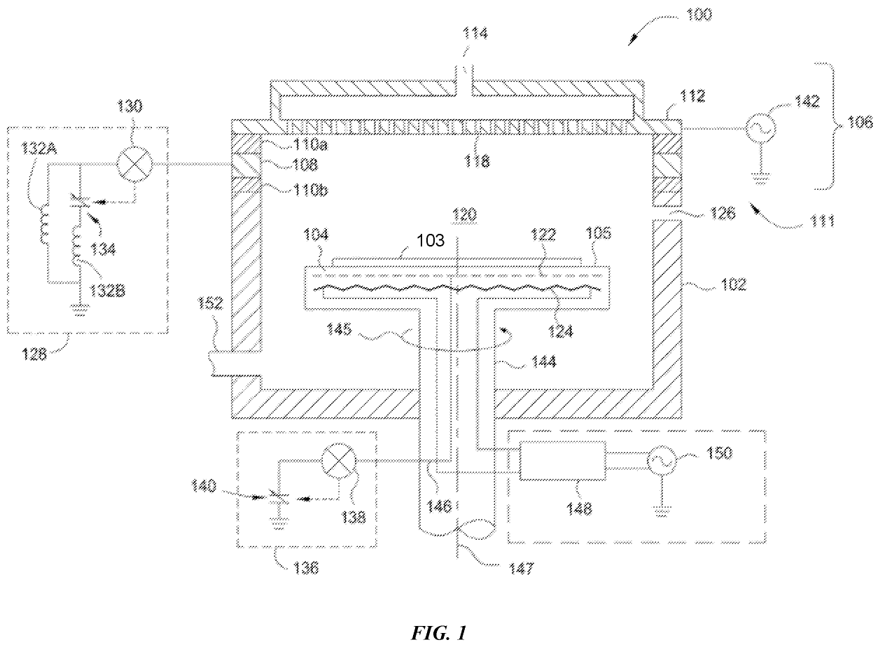

FIG. 1 shows a cross-sectional view of an exemplary processing chamber system 100 according to some embodiments of the present technology. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

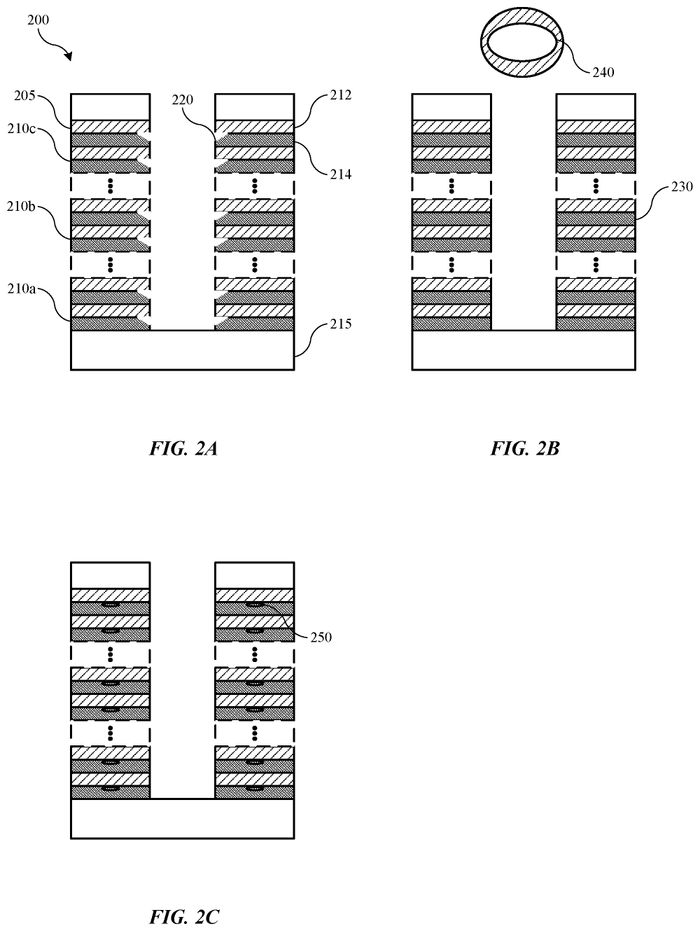

As described previously, reactive ion etching (“RIE”) processes may produce a number of structural effects through stacks of semiconductor materials, which may produce defective devices if not controlled. FIGS. 2A-2C illustrate some structural issues that may occur during memory hole formation. For example, FIG. 2A may show an etching effect known as notching, which may produce sloped defects in silicon nitride layers. The figure includes a structure 200 having a stack 205, which may include multiple portions 210 of alternating layers of materials formed over a substrate 215. Although shown with three portions 210a, 210b, 210c, it is to be understood that stack 205 may include any number of portions in embodiments encompassed by the present technology. Each portion 210 may illustrate four alternating layers of silicon oxide material 212, and silicon nitride material 214. Although four layers are illustrated, it is to be understood that any number of layers may be included in each portion, as well as in the overall stack. Additionally, although illustrated in a particular orientation with silicon nitride being the bottom-most layer, it is to be understood that the layers may be reversed, and may begin with a silicon oxide layer.

As noted above, etching of silicon oxide materials during RIE processes may occur to a greater amount due to ion bombardment, while etching of silicon nitride materials may occur to a greater amount due to chemical reaction between the RIE precursors and the nitride materials. Accordingly, silicon oxide etching may be controlled with control of the RIE beam, and oxide disposed laterally outward from the RIE beam, which may include radially in embodiments, may not be etched. However, nitride materials may be etched based on contact and chemical reaction with the precursors or effluents of the RIE beam. Silicon nitride may also etch more slowly than silicon oxide in some embodiments. Because of hydrogen or other materials associated with silicon nitride, interaction with the effluents of the ME, which may include carbon, may produce an amount of polymeric material, which may passivate or protect sidewalls of the memory hole to limit lateral etching.

However, at an interface between an oxide material and an underlying layer of silicon nitride material, the amount of polymerization may be minimized. Additionally, the etch rate of silicon nitride may be different than that of silicon oxide, which may create increased exposure or effluent residence time at the nitride layer. Prior to formation of the protective polymerization material, such as at a transition between an oxide layer and a nitride layer, the effluents may react with exposed nitride increasing a lateral etch of the material. As polymer buildup occurs, this lateral etch may taper, and a notch 220 may be formed about the leading edge, in the direction of etch, of the silicon nitride material. This notching may impede or affect formation of subsequent layers or material, and may increase the diameter, or critical dimension, of the memory hole in some embodiments.

Resolving notching may include utilizing materials that may better interact at interfacial regions, and the present technology may utilize doped materials, which may include silicon oxynitride as will be described further below. However, oxidizing the silicon nitride layer is often avoided as additional challenges may arise. For example, FIG. 2B may show an example of polygonal distortion, both in vertical cross-section 230, and in horizontal cross-section 240 which may occur during the memory hole formation. Polygonal distortion may refer to the deformation of the memory hole to an ellipsoidal shape instead of a rounded shape formed by the etch process. This type of distortion may occur when silicon oxynitride is utilized, and the higher the oxygen content, the greater the distortion that may be observed. Polygonal distortion may occur when the etch chemistry changes between layers of silicon oxide and silicon oxynitride. Increased byproducts may be produced, and may cause buildup at the top of the structure, which may in turn impact the etch beam and distort the penetration through the structure.

Another issue with silicon oxynitride is illustrated in FIG. 2C, which may show an example of pinhole or void formation within the nitride layer. For example, the figure may illustrate a detailed view of a void 250, which may be an area of less contrast within the nitride layer after formation of the memory hole. Unlike with pure silicon nitride, less polymerization may occur at the interface between a silicon oxide and silicon oxynitride layer. The lower density of the oxynitride may be impacted by the switching chemistry, which may still have increased residence at the interface causing etch damage. Thus, a number of issues may occur during RIE processes, which may affect memory hole structures in a number of ways. The present technology may include one or more adjustments to material properties of the layers of the stack, which may accommodate, offset, or prevent one or more of the challenges described.

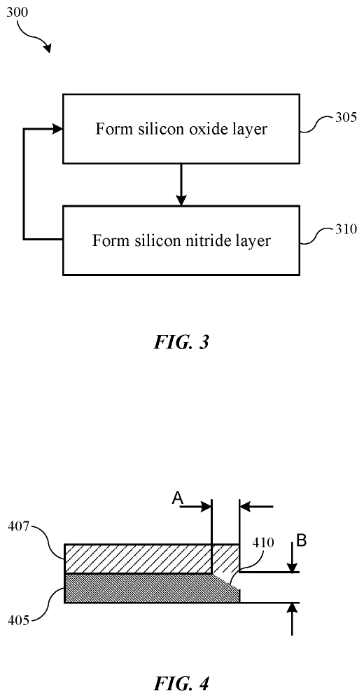

The present technology may adjust material properties of one or more layers or materials within exemplary stacks, which may target one or more of the challenges described above. After generally describing a method of forming one or more portions of a semiconductor material stack of layers, adjustments will be discussed, which may be combined or performed in any variation or combination to improve memory hole formation. The chamber 100 discussed previously may be used in performing exemplary methods including formation methods, although any number of deposition chambers may be used according to embodiments of the present technology. Turning to FIG. 3 is shown exemplary operations in a method 300 for forming a semiconductor structure according to embodiments of the present technology. Prior to the first operation of the method a substrate may be processed in one or more ways before being placed within a processing region of a chamber in which method 300 may be performed. Some or all of the operations may be performed in chambers or system tools as previously described, or may be performed in different chambers on the same system tool, which may include the chamber in which the operations of method 300 may be performed.

Method 300 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 may include formation of a stack of alternating layers of materials, which in some embodiments may be used in 3D NAND memory formation. The alternating layers of material may be produced by any number of methods, including plasma-enhanced chemical vapor deposition, physical vapor deposition, atomic layer deposition, thermally enhanced chemical vapor deposition, or any other formation technique.

In some embodiments, plasma-enhanced chemical vapor deposition may be performed in a processing chamber, such as processing chamber 100 described previously. Although the remaining disclosure will discuss stacks of alternating layers of silicon oxide and silicon nitride, embodiments of the present technology may use different combinations of materials, such as silicon oxide and silicon, silicon nitride and silicon, silicon and doped silicon, or any number of other materials. Although the method 300 will discuss formation of silicon oxide followed by formation of silicon nitride, the formation order may be reversed in embodiments similarly encompassed by the present technology. Additionally, any number of layers of material may be produced in a stack, or any portion of any stack, and different portions of a stack may include more, less, or similar numbers of layers of any other portion of a stack according to embodiments of the present technology.

Method 300 may include forming a silicon oxide layer on a substrate at operation 305. The formation may be performed with a silicon-containing precursor and an oxygen-containing precursor. The method may also include forming a silicon nitride layer overlying the silicon oxide layer at operation 310. The formation may be performed with a silicon-containing precursor and a nitrogen-containing precursor. These operations may be repeated any number of times until a predetermined number of pairs of layers may be formed that may constitute a stack of layers, which may include greater than or about 2 pairs, greater than or about 10 pairs, greater than or about 50 pairs, greater than or about 100 pairs, or more pairs of layers. Any specific number of pairs encompassed by any of these stated ranges is to be understood as if specifically stated here.

In some embodiments, multiple portions, including all portions, may be formed during operations 305 and 310, although in some embodiments the portions may be produced in multiple operations. For example, one or more optional operations may be performed between formation of an overlying portion of a stack, or adjustments as will be described below may occur between any of the portions, which may be indicated as a different portion. For example, a high temperature anneal may be performed prior to formation of a second portion of the stack. Optional operations may also include formation of a first portion of a memory hole, as well as adjustments to precursors. A second portion of the stack may be formed by formation of at least one layer of a silicon oxide material, and formation of at least one layer of a silicon nitride material, and which may be repeated to produce any number of pairs of layers similar to the first portion as noted above.

A mask material may be formed over any of the portions of the stack prior to forming a portion of a memory hole or other feature through the structure. Structures according to the present technology may be characterized by any aspect ratios or the height-to-width ratio of the structure, although in some embodiments the materials may be characterized by larger aspect ratios, which may increase effects on aspects of the produced structure as described previously. For example, in some embodiments the aspect ratio of exemplary structures, such as the depth of the aperture or memory hole relative to the cross-sectional diameter, may be greater than or about 10:1, greater than or about 20:1, greater than or about 30:1, greater than or about 40:1, greater than or about 50:1, or greater. These high aspect ratios may frustrate many conventional etching operations or produce or exacerbate any of the issues described previously.

The substrate on which the pairs of material may be formed may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate may have various dimensions, such as 200 mm or 300 mm diameter wafers, as well as rectangular or square panels. Silicon-containing precursors that may be used during either of the silicon oxide formation or the silicon nitride formation may include, but are not limited to, silane (SiH₄), disilane (Si₂H₆), silicon tetrafluoride (SiF₄), silicon tetrachloride (SiCl₄), dichlorosilane (SiH₂Cl₂), tetraethyl orthosilicate (TEOS), as well as any other silicon-containing precursors that may be used in silicon-containing film formation. Oxygen-containing precursors used in any operation as described throughout the present technology may include O₂, N₂O, NO₂, O₃, H₂O, as well as any other oxygen-containing precursors that may be used in silicon oxide film formation, silicon oxynitride film formation, or other film formation. Nitrogen-containing precursors used in any operation may include Na, N₂O, NO₂, NH₃, N₂H₂, as well as any other nitrogen-containing precursor that may be used in silicon nitride film formation. Additional dopant precursors may include PH₃ or any other phosphorus-containing precursor. In any of the formation operations one or more additional precursors may be included, such as inert precursors, which may include Ar, He, Xe, Kr, nitrogen, hydrogen, or other precursors.

As noted previously, notching may occur in silicon nitride layers during memory hole formation due to reactive species diffusing laterally through the structure prior to formation of sufficient polymerization. However, in some embodiments, formation of the silicon nitride layer may include incorporation of an amount of oxygen. As described above, the RIE process may occur to a greater degree from bombardment with oxygen, and by incorporating oxygen into the nitride layer to a controlled amount, notching may be reduced or removed in some embodiments. For example, during formation of one or more of the silicon nitride layers in any of the portions of the stack, an oxygen-containing precursor may be flowed with the nitrogen-containing precursor and/or the silicon-containing precursor to produce a film incorporating an amount of oxygen. The oxygen-containing precursor may be any of the oxygen-containing precursors noted above, and in some embodiments may be the same oxygen-containing precursor used in formation of the silicon oxide material. By using the same precursor in some embodiments, fewer modifications may be made during formation of the stack, which may reduce queue times.

In some embodiments one or more of the layers of silicon nitride material may include greater than or about 5 at. % oxygen, and may include greater than or about 10 at. % oxygen, greater than or about 15 at. % oxygen, greater than or about 20 at. % oxygen, greater than or about 25 at. % oxygen, greater than or about 30 at. % oxygen, or more. Additional incorporation of oxygen may affect downstream processes, such as exhuming the silicon nitride layer, and thus in some embodiments the amount of oxygen may be maintained below or about 30 at. % oxygen, below or about 25 at. % oxygen, below or about 20 at. % oxygen, or lower, which may facilitate selective removal of the nitride material during subsequent operations, without compromising the silicon oxide materials. Similarly, in some embodiments one or more of the layers of silicon nitride material may include phosphorus, which may be incorporated within the film at a concentration of less than or about 15 at. %, and may be incorporated at a concentration of less than or about 12 at. %, less than or about 10 at. %, less than or about 8 at. %, less than or about 6 at. %, less than or about 5 at. %, less than or about 4 at. %, less than or about 3 at. %, less than or about 2 at. %, less than or about 1 at. %, or less. In some embodiments the layers of silicon nitride material may maintain an amount of nitrogen above a threshold, such as greater than or about 20 at. %, and may produce silicon nitride materials characterized by an amount of nitrogen greater than or about 25 at. %, greater than or about 30 at. %, greater than or about 35 at. %, greater than or about 40 at. %, greater than or about 45 at. %, or higher.

As noted above, notching may occur at a leading edge of the silicon nitride materials in a direction of etch towards the substrate. In some embodiments the incorporation of oxygen may be tailored to accommodate this effect. For example, in some embodiments the formation of silicon nitride materials may include formation of a bi-layer of silicon nitride and silicon oxynitride and/or phosphorus-doped silicon nitride for each layer of silicon nitride. For example, a silicon-containing precursor and a nitrogen-containing precursor may be flowed to produce an amount of silicon nitride, and then an oxygen-containing precursor and/or phosphorus-containing precursor may be added to the flows, which may include maintaining or adjusting the flow rates of the silicon-containing precursor and/or the nitrogen-containing precursor. Each layer of the bi-layer may constitute any percentage of the bi-layer between about 10% and about 90% of a thickness of the bi-layer. However, in some embodiments the doped portion of the bilayer, for example the oxygen and/or phosphorus-containing portion may constitute less than or about 50% of the bilayer in order to maintain differentiation between the layers, and facilitate downstream processing, which may selectively remove the silicon nitride materials. Additionally, the oxygen and/or phosphorus-containing portion may constitute less than or about 45% of the bilayer, less than or about 40% of the bilayer, less than or about 35% of the bilayer, less than or about 30% of the bilayer, less than or about 25% of the bilayer, less than or about 20% of the bilayer, less than or about 15% of the bilayer, less than or about 10% of the bilayer, or less.

Whether the oxygen/phosphorus-containing dopant precursor may be added initially during the formation of the silicon nitride material, or added at some time after initial formation, the flow rate of the dopant precursor may be held constant, may be decreased, or may be increased during formation of the layer. For example, a gradient of dopant concentration may be produced within the silicon nitrogen material from about 0 at. % dopant incorporation up to any of the previously noted incorporations. By initiating, and then adjusting, the flow rate of the dopant precursor, the silicon nitride material may include a gradient of incorporation. For example, the flow rate of the dopant precursor may be increased during formation of the layer of silicon nitride material, or bi-layer, so a portion of silicon nitride material at an interface of an overlying silicon oxide material may be characterized by an increased amount of dopant over an underlying portion of the silicon nitride material. Accordingly, a notching effect may be reduced where it is most likely to occur, while maintaining more of a nitride incorporation throughout the film in some embodiments.

The amount of dopant incorporated in one or more layers of silicon nitride material may also be adjusted between different portions of the stack in some embodiments, and any layer in any portion may be characterized by any amount of dopant incorporation as noted above, or may remain substantially free of dopant incorporation. For example, some striation effects and/or profile variation may occur in a second portion of the stack. By adjusting the dopant incorporation in the silicon nitride in this portion of the stack, these issues may be limited or resolved. For example, some bowing and striation may occur due to radical effluents of the RIE process laterally etching silicon nitride, which may expose additional silicon oxide and increase an amount of etch on those materials, increasing the effect. By limiting the effect on the nitride materials, the effect on the oxide materials may also be reduced, improving these issues and the uniformity of the memory hole formation. By increasing the dopant incorporation in the nitride layers in regions where striation and/or bowing may occur, resistance to lateral etch may be increased, which may limit the effects of these issues.

Similarly, memory hole alignment and distortion issues may be improved such as by increasing the dopant concentration in nitride materials in underlying portions of the stack. Silicon oxide may afford improved control on stress effects by reducing an amount of hydrogen within the film, or otherwise affording more control on stress effects, which may limit deformities described previously. Accordingly, in some embodiments, a first portion of the stack may include increased dopant concentration in the nitride layers, which may reduce stress effects due to outgassing. An optional anneal may also be performed as previously described, which may raise the temperature of the formed films, either with or without increased dopant concentration in the nitride materials, and which may increase outgassing prior to formation of an additional portion of the stack. The anneal may include a process increasing the temperature of the first portion of the stack greater than or about 500° C., and which may increase the temperature of the first portion of the stack greater than or about 550° C., greater than or about 600° C., greater than or about 650° C., greater than or about 700° C., greater than or about 750° C., greater than or about 800° C., greater than or about 850° C., greater than or about 900° C., or higher. When temperatures exceed about 650° C., for example, an amount of outgassing may occur to limit deformation of the structure to afford improved alignment between portions of a memory hole.

Similarly, the deposition operation may also be performed at a higher temperature, which may additionally increase density of the doped silicon nitride film. For example, in some embodiments the silicon nitride may be formed at a substrate temperature of greater than or about 400° C., and may be performed at a substrate temperature of greater than or about 450° C., greater than or about 500° C., greater than or about 550° C., greater than or about 600° C., greater than or about 650° C., or higher. In combination with controlled dopant incorporation, as well as plasma modification as will be described below, this may allow the density of the silicon nitride film to be tuned across a range of densities. For example, either as a bilayer or as a continuous layer, the silicon nitride may have regions characterized by a density below the density of silicon nitride, although the density may be maintained higher than silicon oxynitride, which may ensure pinholes and polygonal distortion may be controlled or prevented in embodiments of the present technology. Accordingly, density within the silicon nitride layer may range from greater than or about 3.0 g/cm³, or greater than or about 3.1 g/cm³, up to the density of silicon nitride, or may be reduced in any portion of the film to include a density of less than or about 3.0 g/cm³, and may include a density of less than or about 2.95 g/cm³, less than or about 2.9 g/cm³, less than or about 2.85 g/cm³, less than or about 2.8 g/cm³, less than or about 2.75 g/cm³, less than or about 2.7 g/cm³, less than or about 2.65 g/cm³, less than or about 2.6 g/cm³, or less.

By including an amount of dopant within the nitride materials, notching can be reduced or removed in some embodiments of the present technology. FIG. 4 illustrates a close-up view of an underlying layer of silicon nitride material 405 and an overlying portion of a silicon oxide material 407, where a notch 410 may be formed. The notch may be characterized by a distance A of intrusion laterally at an interface between the silicon nitride layer and the overlying silicon oxide material. The layer of silicon nitride material may also be characterized by a thickness B. In some embodiments, any particular layer of silicon nitride material may include a notch having a distance A of intrusion that may be less than or about 100% of a distance corresponding to a thickness B. In some embodiments, distance A may be less than or about 75% of distance B, distance A may be less than or about 50% of distance B, distance A may be less than or about 40% of distance B, distance A may be less than or about 30% of distance B, distance A may be less than or about 20% of distance B, distance A may be less than or about 10% of distance B, distance A may be less than or about 5% of distance B, distance A may be less than or about 1% of distance B, or the distance A may be zero, in which no notch may be formed in the layer.

Dopant concentrations may also be adjusted to impact etch rate of the silicon nitride materials, which may improve etching, such as in the first portion of the stack, where a taper or narrowing may occur. These dopants may have an affinity to particular materials in an RIE chemistry, which may increase the etching through the portion. Accordingly, incorporating these dopants may increase etching of the materials. Similarly, silicon nitride may be formed with an increased carbon incorporation, which may reduce etching in some portions. Many RIE etchants may include halocarbons, such as chlorocarbons, fluorocarbons, or chloroflouorcarbons, which may have reduced etching of films incorporating an increased amount of carbon relative to films having lower amounts of carbon. Hence, as one non-limiting example, one or more layers or one or more portions of the stack may include an increased carbon concentration, such as between about 1% and about 10%, to control etching.

The ratio of nitrogen to silicon within a layer of silicon nitride material may also be adjusted in some embodiments to affect etch rate. For example, by increasing the ratio of nitrogen to silicon, etch rate of materials may be increased, and by reducing the ratio of nitrogen to silicon, etch rate of materials may be decreased. Accordingly, in some embodiments one or more layers of silicon nitride materials may be characterized by an increased nitrogen to silicon ratio relative to one or more other layers, such as in a first portion, for example, and/or one or more layers of silicon nitride materials may be characterized by a decreased nitrogen to silicon ratio relative to one or more other layers, such as in a second portion, for example. An increased nitrogen to silicon ratio may be greater than or about 1.3, and may be greater than or about 1.4, greater than or about 1.5, greater than or about 1.6, or higher. A decreased nitrogen to silicon ratio may be less than or about 1.3, and may be less than or about 1.2, be less than or about 1.1, be less than or about 1.0, or less.

Adjusting the plasma formation process may also facilitate formation of the silicon nitride layers by affecting the removal of hydrogen from films being produced in some embodiments. For example, some embodiments of the present technology may include pulsing the plasma power during plasma generation for forming the silicon nitride layer. In some embodiments plasma pulsing may be applied to one or both of the silicon oxide or silicon nitride formation. The plasma may be generated at a plasma-generation frequency, such as 13.56 MHz in one non-limiting example. The plasma power may also be pulsed at a pulsing frequency that may be less than or about 10 kHz, and may be less than or about 9 kHz, less than or about 8 kHz, less than or about 7 kHz, less than or about 6 kHz, less than or about 5 kHz, less than or about 4 kHz, less than or about 3 kHz, less than or about 2 kHz, less than or about 1 kHz, or less. The duty cycle of the pulsing frequency may provide an amount of “off” time for the plasma generation.

During plasma “off” periods, deposition may not be occurring. While previously formed ions may quickly extinguish, radical species may still contact the heated substrate and transfer energy into the amorphous lattice being produced. This may continue to activate and break additional hydrogen bonds within the film, which may then be removed from the film. At high duty cycle, insufficient time may be afforded for this effect before deposition resumes. Accordingly, in some embodiments, the duty cycle may be maintained at less than or about 50%, and may be maintained at less than or about 45%, less than or about 40%, less than or about 35%, less than or about 30%, less than or about 25%, less than or about 20%, less than or about 15%, less than or about 10%, less than or about 5%, or less.

By utilizing one or more of the described processes, improved formation of memory holes may be afforded, which may limit effects such as notching, as well as improve uniformity of a profile through the memory hole. For example, in some embodiments, layers or portions through a stack may be characterized by variation in diameter through the memory hole of the stack of less than or about 200%, and may be characterized be variation in diameter through the memory hole of less than or about 150%, less than or about 100%, less than or about 90%, less than or about 80%, less than or about 70%, less than or about 60%, less than or about 50%, less than or about 40%, less than or about 30%, less than or about 20%, less than or about 10%, or less. Consequently, improved fabrication may be afforded by the present technology, which may produce more uniform stack structures over conventional technologies.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of forming a semiconductor structure, the method comprising:
forming a silicon oxide layer from a silicon-containing precursor and an oxygen-containing precursor;
forming a silicon nitride layer from a silicon-containing precursor, a nitrogen-containing precursor, and an oxygen-containing precursor, wherein the silicon nitride layer is characterized by an oxygen concentration less than or about 30 at. % and a density of less than or about 3.0 g/cm³; and
repeating the forming a silicon oxide layer and the forming a silicon nitride layer to produce a stack of alternating layers of silicon oxide and silicon nitride.

2. The method of forming a semiconductor structure of claim 1, wherein the oxygen-containing precursor of the forming a silicon oxide layer and the oxygen-containing precursor of the forming a silicon nitride layer are the same precursor.

3. The method of forming a semiconductor structure of claim 1, wherein forming the silicon nitride layer comprises performing a plasma-enhanced deposition at a substrate temperature of greater than or about 500° C.

4. The method of forming a semiconductor structure of claim 1, wherein forming the silicon nitride layer comprises performing a plasma-enhanced deposition at a plasma pulsing frequency of less than or about 10 kHz and a duty cycle of less than or about 50%.

5. The method of forming a semiconductor structure of claim 1, wherein the oxygen concentration of the silicon nitride layer is between about 10 at. % and about 30 at. %, and wherein a nitrogen atomic percent is greater than or about 30 at. %.

6. The method of forming a semiconductor structure of claim 1, wherein forming the silicon nitride layer comprises:
flowing the silicon-containing precursor and the nitrogen-containing precursor into a substrate processing region,
forming an amount of silicon nitride, and
adding the oxygen-containing precursor while continuing to form silicon nitride.

7. The method of forming a semiconductor structure of claim 6, wherein the oxygen-containing precursor is flowed at a constant flow rate, and wherein the silicon nitride layer formed comprises a bi-layer of silicon nitride substantially free of oxygen and silicon nitride characterized by an oxygen concentration greater than or about 5 at. %.

8. The method of forming a semiconductor structure of claim 6, wherein the oxygen-containing precursor is flowed at a varying flow rate, and wherein the silicon nitride layer formed comprises a gradient of oxygen concentration through the silicon nitride layer.

9. The method of forming a semiconductor structure of claim 8, wherein a flow rate of oxygen-containing precursor is increased during the adding the oxygen-containing precursor.

10. The method of forming a semiconductor structure of claim 1, further comprising forming one or more features through the stack of alternating layers of silicon oxide and silicon nitride.

11. The method of forming a semiconductor structure of claim 10, wherein a lateral removal of the silicon nitride layer at an interface of the silicon nitride layer and an overlying silicon oxide layer extends a distance less than or about 50% of a distance corresponding to a thickness of the silicon nitride layer.

12. A method of forming a semiconductor structure, the method comprising:
forming a silicon oxide layer from a silicon-containing precursor and an oxygen-containing precursor;
forming a silicon nitride layer from a silicon-containing precursor, a nitrogen-containing precursor, and a phosphorus-containing precursor, wherein the silicon nitride layer is characterized by a phosphorus concentration less than or about 15 at. % and a density of less than or about 3.0 g/cm³; and
repeating the forming a silicon oxide layer and the forming a silicon nitride layer to produce a stack of alternating layers of silicon oxide and silicon nitride.

13. The method of forming a semiconductor structure of claim 12, wherein forming the silicon nitride layer comprises performing a plasma-enhanced deposition at a substrate temperature of greater than or about 500° C.

14. The method of forming a semiconductor structure of claim 12, wherein forming the silicon nitride layer comprises performing a plasma-enhanced deposition at a plasma pulsing frequency of less than or about 10 kHz and a duty cycle of less than or about 50%.

15. The method of forming a semiconductor structure of claim 12, wherein the phosphorus concentration of the silicon nitride layer is less than or about 10 at. %, and wherein a nitrogen atomic percent is greater than or about 30 at. %.

16. The method of forming a semiconductor structure of claim 12, wherein forming the silicon nitride layer comprises:
flowing the silicon-containing precursor and the nitrogen-containing precursor into a substrate processing region,
forming an amount of silicon nitride, and
adding the phosphorus-containing precursor while continuing to form silicon nitride.

17. The method of forming a semiconductor structure of claim 16, wherein the phosphorus-containing precursor is flowed at a constant flow rate, and wherein the silicon nitride layer formed comprises a bi-layer of silicon nitride substantially free of phosphorus and silicon nitride characterized by an phosphorus concentration greater than or about 1 at. %.

18. The method of forming a semiconductor structure of claim 16, wherein phosphorus is incorporated in less than or about 30% of a thickness of the silicon nitride layer.

19. A method of forming a semiconductor structure, the method comprising:
forming a silicon oxide layer from a silicon-containing precursor and an oxygen-containing precursor;
forming a silicon nitride layer from a silicon-containing precursor, a nitrogen-containing precursor, and a dopant precursor, wherein the silicon nitride layer is characterized by a dopant concentration less than or about 30 at. % and a density of less than or about 3.0 g/cm³; and
repeating the forming a silicon oxide layer and the forming a silicon nitride layer to produce a stack of alternating layers of silicon oxide and silicon nitride.

20. The method of forming a semiconductor structure of claim 19, wherein forming the silicon nitride layer comprises performing a plasma-enhanced deposition at a substrate temperature of greater than or about 500° C., and wherein forming the silicon nitride layer comprises performing the plasma-enhanced deposition at a plasma pulsing frequency of less than or about 10 kHz and a duty cycle of less than or about 50%.
